(19) United States
(12) Patent Application Publication
(10) Pub. No.: US 2014/0116498 A1
(43) Pub. Date: May 1, 2014

(54) PHOTOVOLTAIC MODULE

(71) Applicant: HON HAI PRECISION INDUSTRY CO., LTD., New Taipei (TW)

(72) Inventor: Kai-Ming Lu, New Taipei (TW)

(73) Assignee: HON HAI PRECISION INDUSTRY CO., LTD., New Taipei (TW)

(21) Appl. No.: 13/705,197

(22) Filed: Dec. 5, 2012

(30) Foreign Application Priority Data
Oct. 30, 2012 (CN) 2012104228484

(51) Int. Cl. H01L 31/042

(52) U.S. Cl. CPC H01L 31/0424
USPC 136/251

(57) ABSTRACT

A photovoltaic module includes a photovoltaic sheet and a number of bars around the photovoltaic sheet. Each bar includes a supporting plate and a locking plate. A channel is defined between the supporting plate and the locking plate, to receive an edge of the photovoltaic sheet. One of the bars arranged at a bottom of the photovoltaic module defines at least one discharge groove, communicating with the channel, which causes accumulating grime and dirt to be thrown off by the action of rain or by cleaning.

### BACKGROUND

1. Technical Field

The present disclosure relates to photovoltaic modules and, particularly, to a photovoltaic module including a frame.

2. Description of Related Art

A photovoltaic module includes a photovoltaic panel or sheet and a frame around the photovoltaic panel or sheet. Grime and dirt is always accumulating on the photovoltaic panel or sheet, particularly in places close to the frame. Therefore, there is room for improvement in the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a photovoltaic module.

FIG. 2 is an enlarged view of circled part II of FIG. 1.

FIG. 3 is a partially assembled, isometric view of the items in FIG. 2.

FIG. 4 is a cross-sectional view taken along line IV-IV of FIG. 3.

### DETAILED DESCRIPTION

The disclosure, including the accompanying drawings in which like references indicate similar elements, is illustrated by way of examples and not by way of limitation. It should be noted that references to “an” or “one” embodiment in this disclosure are not necessarily to the same embodiment, and such references mean “at least one.”

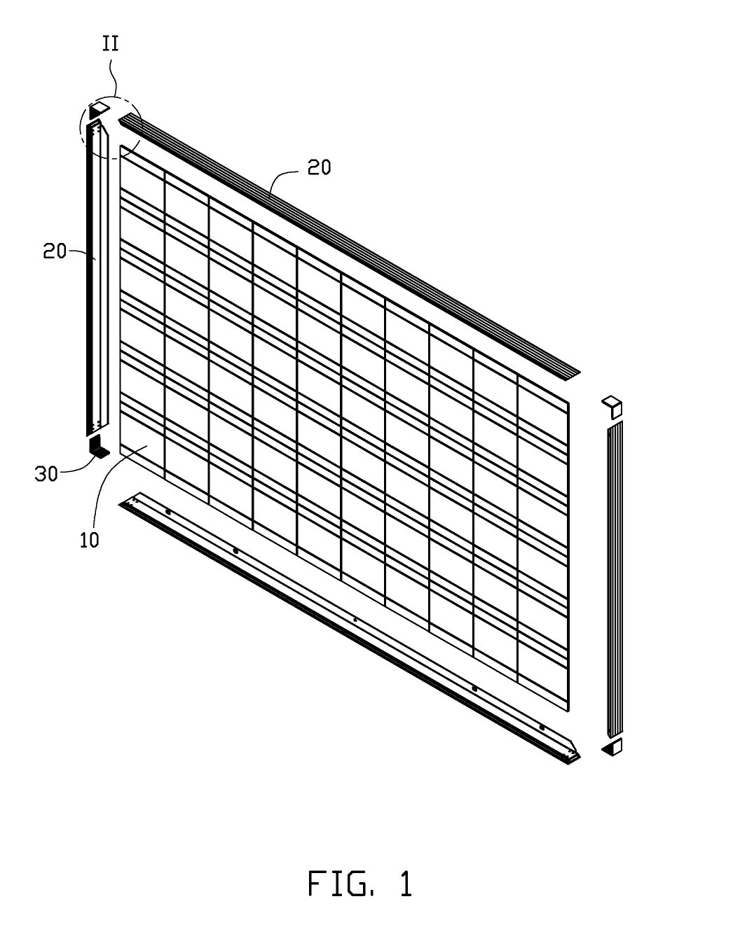

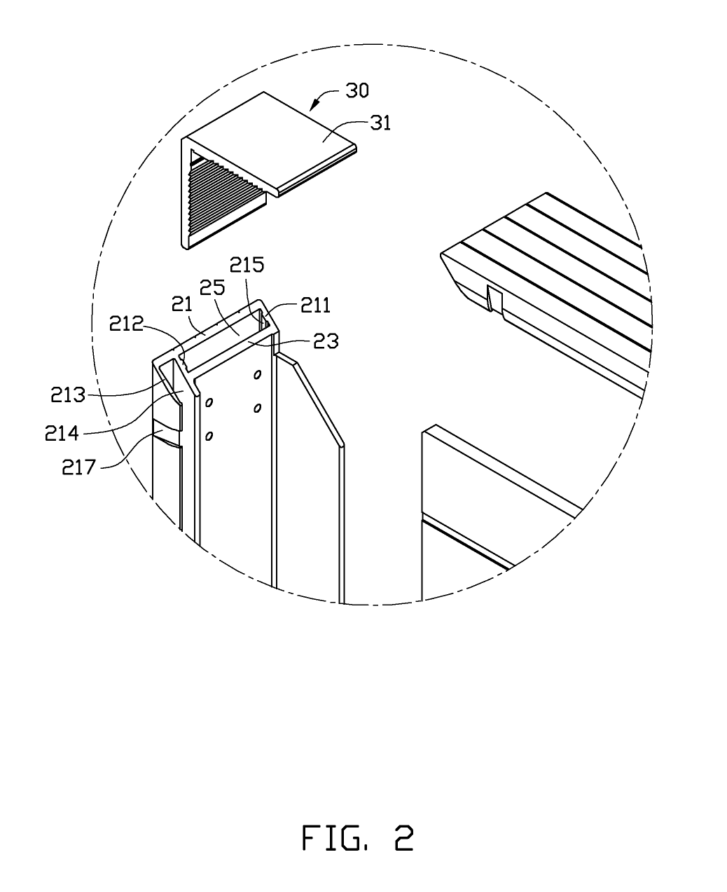

Referring to FIG. 1 and FIG. 2, an embodiment of a photovoltaic module includes a rectangular photovoltaic sheet 10 and a frame around the photovoltaic sheet 10. The frame includes four bars 20 and four connecting members 30 connecting every two adjacent bars 20. In the embodiment, the bars 20 are made of aluminum.

Each bar 20 includes an outer plate 21, an inner plate 23 parallel to the outer plate 21, a side plate 211 between first sides of the outer plate 21 and the inner plate 23, a supporting plate 212 between second sides of the outer plate 21 and the inner plate 23, and a locking plate 213 extending from an edge of the outer plate 21 adjacent to the second side of the outer plate 21 and parallel to the supporting plate 212. The outer plate 21, the inner plate 23, the side plate 211, and the supporting plate 212 together bound a receiving space 25. The supporting plate 212, the locking plate 213, and the outer plate 21 together bound a channel 214 for receiving an edge of the photovoltaic sheet 10. A raised portion 215 extends into the receiving space 25 from an inner surface of each of the side plate 211 and the supporting plate 212, the length of the raised portion 215 being at least equal to the length of one connecting plate of each connecting member 30, as hereinafter described. A discharge groove 217 is defined in each end of the locking plate 213 and the discharge groove 217 communicates with the channel 214.

Each connecting member 30 is substantially L shaped, and includes two connecting plates 31 perpendicular to each other.

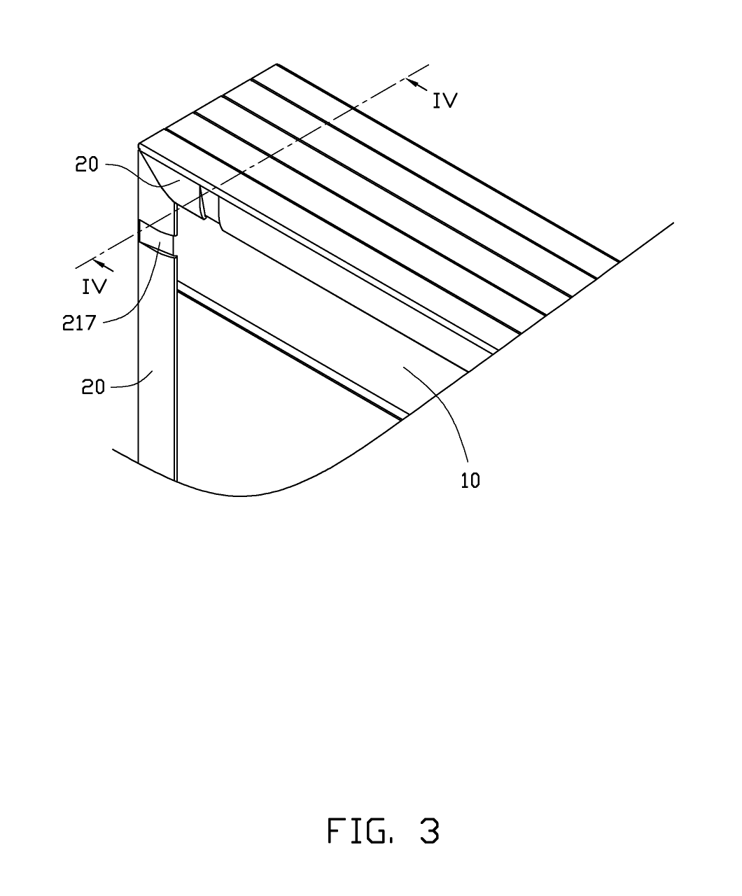

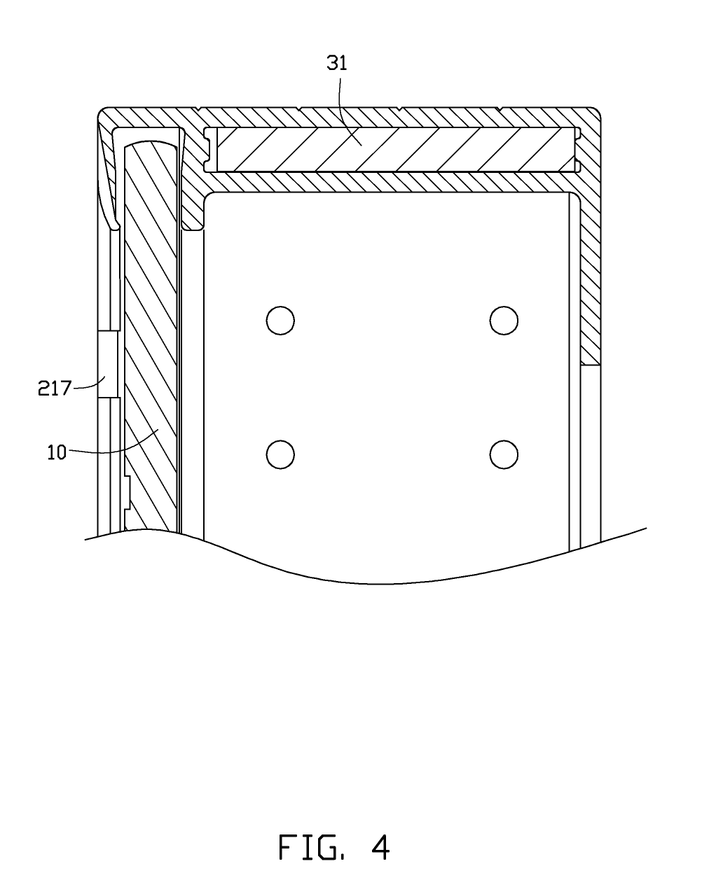

Referring to FIG. 3 and FIG. 4, in assembly, each of the connecting plates 31 is pressed into a receiving space 25 of each bar 20, until all the inner plates 23 abut one another. The raised portions 215 exert slight pressure on the opposite edges of the connecting plate 31. Four edges of the photovoltaic sheet 10 are received in the channels 214 of the bars 20. Thus the four bars 20 are connected end to end around the photovoltaic sheet 10. The photovoltaic module can be slantingly mounted to a bracket (not shown). The action of rain, or when the photovoltaic sheet 10 is cleaned, the grime and dirt accumulating on the photovoltaic sheet 10 will be discharged through the discharge grooves 217.

In this embodiment, each bar 20 defines one or several discharge grooves 217. In another embodiment, only one bar 20, arranged at a bottom of the photovoltaic module, defines one or more discharge grooves 217.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A photovoltaic module, comprising:
a photovoltaic sheet; and
a plurality of bars connected end to end around the photovoltaic sheet, wherein each bar comprises a supporting plate and a locking plate, a channel is defined between the supporting plate and the locking plate, to receive one side of the photovoltaic sheet;
wherein one of the bars arranged at a bottom of the photovoltaic module defines at least one discharge groove communicating with the channel of the bar.

2. The photovoltaic module of claim 1, wherein each of the bars comprises an outer plate and an inner plate parallel to the outer plate, a side plate is connected between first sides of the outer plate and the inner plate, the supporting plate is connected between second sides of the outer plate and the inner plate, the locking plate extends from an edge of the outer plate adjacent to the second side of the outer plate and is parallel to the supporting plate, the supporting plate, the locking plate, and the outer plate together bound the channel for receiving the corresponding side of the photovoltaic sheet.

3. The photovoltaic module of claim 2, wherein the plurality of bars comprises four bars, four L-shaped connecting members are connected between every two adjacent bars, each connecting member comprises two connecting plates, the outer plate, the inner plate, the side plate, and the supporting plate together bound a receiving space, each connecting plate is pressed into a receiving space of each of the bars.

4. The photovoltaic module of claim 1, wherein each of the other ones of the bars defines at least one discharge groove communicating with the corresponding channel of the bar.
